(19) United States
(12) Patent Application Publication
(10) Pub. No.: US 2003/0117207 A1
(43) Pub. Date: Jun. 26, 2003

(54) Level shifter having plurality of outputs

(76) Inventors: Yang Yil Suk, Daejeon (KR); Kim Jong Dae, Taejon (KR)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/062,872

(22) Filed: Jan. 31, 2002

(30) Foreign Application Priority Data
Dec. 21, 2001 (KR) 01-72640

(51) Int. Cl. H03L 5/00

(52) U.S. Cl. 327/333

(57) ABSTRACT

A level shifter for generating a plurality of output voltages having a plurality of levels to interface a low voltage circuit with a high voltage circuit is provided. The level shifter includes a first level shifter for receiving an input signal and a first power supply and outputting a first output voltage having a level the same as that of a ground voltage or the first power supply according to the input signal, a first control signal having a value in which the first output voltage is inverted, and a second control signal having the same value as that of the first output voltage, and an output voltage generator for receiving the first power supply and a second power supply having a level different from that of the first power supply and outputting a second output voltage having a level equivalent to either the first power supply or the second power supply according to the first and second control signals. The level shifter can output voltages having levels different according to a power supply applied to one level shifter, and thus, interface a low voltage circuit with a high voltage circuit can be very easily made and various applications thereof are possible.

### BACKGROUND OF THE INVENTION

1. Field of the Invention

The present invention relates to a level shifter, and more particularly, to a level shifter for generating a plurality of output voltages having a plurality of levels.

2. Description of the Related Art

Referring to FIG. 1, in general, a level shifter is used to interface a circuit driven by a low voltage V_{DDL} with a circuit driven by a high voltage V_{DDH} in a circuit including the low voltage V_{DDL} and the high voltage V_{DDH}.

However, a conventional voltage level shifter outputs only one selected from either 0V or a power supply applied to the voltage level shifter according to an input signal. Thus, when a voltage having a plurality of levels is required, at least two or more voltage level shifters are required.

### SUMMARY OF THE INVENTION

To solve the above problems, it is an object of the present invention to provide a level shifter for generating a plurality of output voltages having a plurality of levels.

Accordingly, to achieve the object, there is provided a level shifter. The level shifter includes a first level shifter for receiving an input signal and a first power supply and outputting a first output voltage having a level the same as that of a ground voltage or the first power supply according to the input signal, a first control signal having a value in which the first output voltage is inverted, and a second control signal having the same value as that of the first output voltage, and an output voltage generator for receiving the first power supply and a second power supply having a level different from that of the first power supply and outputting a second output voltage having a level equivalent to either the first power supply or the second power supply according to the first and second control signals.

### BRIEF DESCRIPTION OF THE DRAWINGS

The above objects and advantages of the present invention will become more apparent by describing in detail a preferred embodiment thereof with reference to the attached drawings in which:

FIG. 1 is a block diagram illustrating that a circuit for operating at a logic level is interfaced with a circuit for operating at a high voltage level by a level shifter;

FIG. 2 is a block diagram of a level shifter according to the present invention;

FIG. 3 is a detailed circuit diagram of FIG. 2;

FIG. 4 illustrates a waveform of an input signal and an output signal of the level shifter according to the present invention; and

FIG. 5 illustrates results of simulation of the operation of the level shifter according to the present invention.

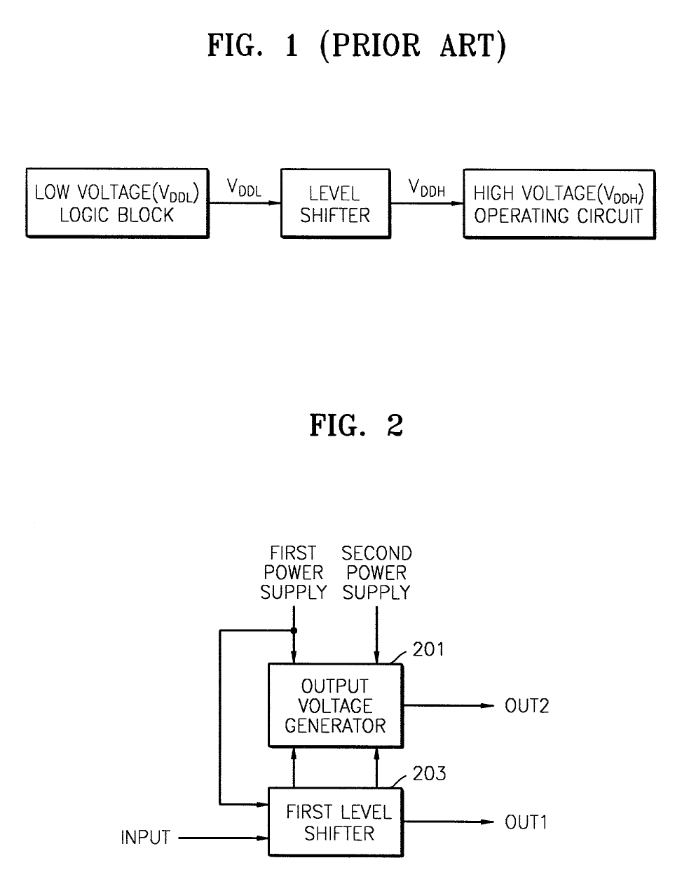

### DETAILED DESCRIPTION OF THE INVENTION

Hereinafter, the present invention will be described in detail by describing preferred embodiments of the invention with reference to the accompanying drawings.

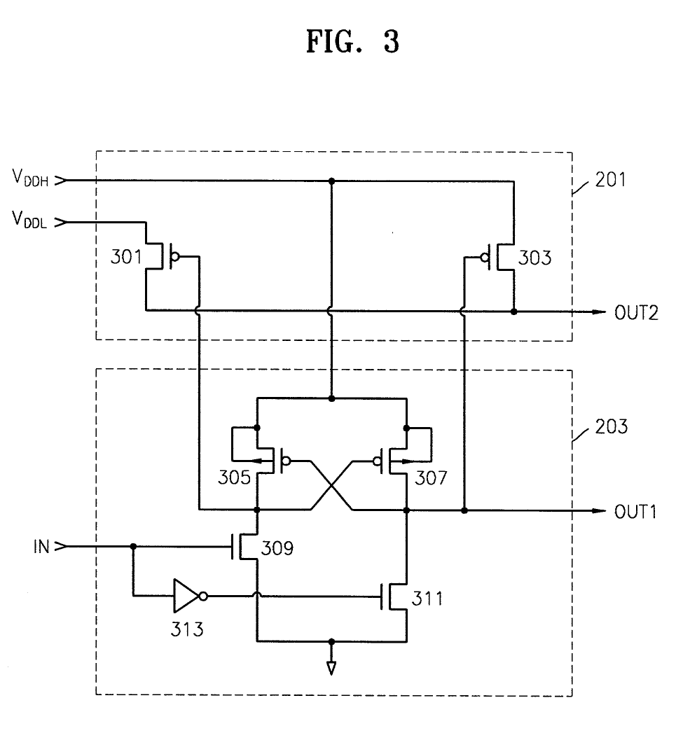

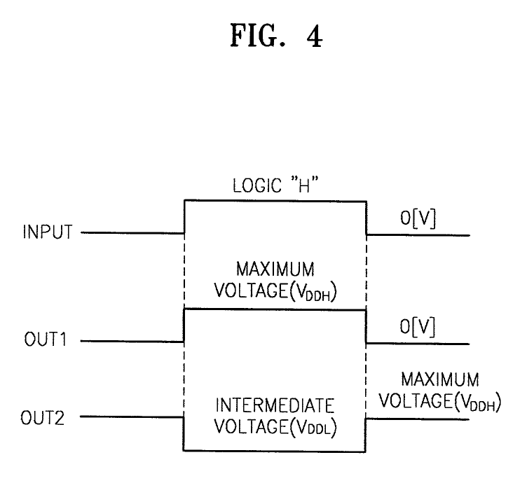

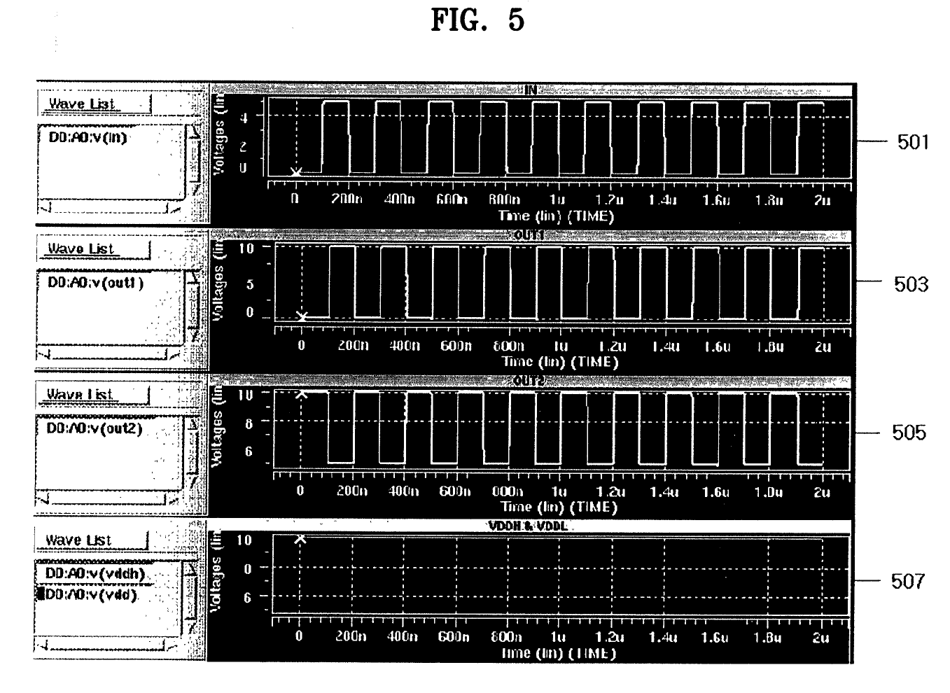

FIG. 2 is a block diagram of a level shifter according to the present invention, and FIG. 3 is a detailed circuit diagram of FIG. 2. In the embodiment, two input power supplies, that is, first and second power supplies V_{DDH} and V_{DDL} are applied to the level shifter. The first power supply V_{DDH} (referred to as ‘maximum voltage’ in FIG. 4) has a level higher than the second power supply V_{DDL}, and the second power supply V_{DDL} (referred to as ‘intermediate voltage’) has a level between a ground voltage and the first input power supply. Referring to FIG. 2, a first level shifter 203 receives an input signal IN and the first power supply V_{DDH}. The first power supply V_{DDH} has a voltage level required to be interfaced with a high voltage circuit to which the level shifter is connected. The first level shifter 203 outputs voltages according to the input signal IN, for example, the first level shifter 203 outputs the ground voltage (0V) when the input signal IN is logic “low (0)” and outputs a first output voltage OUT1 having a voltage level the same as that of the first power supply V_{DDH} when the input signal IN is logic “high (1)” according to the input signal IN. The first level shifter 203 outputs first and second control signals for controlling an output voltage generator 201 for generating a second output voltage OUT2. The output voltage generator 201 receives the first and second power supplies V_{DDH} and V_{DDL} and generates the second output voltage OUT2 according to the first and second control signals, which are output from the first level shifter 203. The second output voltage OUT2 has the same level as that of the first power supply V_{DDH} or the second power supply V_{DDL}. Thus, the first output voltage OUT1 and the second output voltage OUT2 having different levels according to the logic level of the input signal IN are simultaneously generated.

The embodiment will be described in greater detail with reference to FIG. 3.

The output voltage generator 201 includes two PMOS transistors 301 and 303. The first level shifter 203 includes two PMOS transistors, that is, first and second PMOS transistors 305 and 307, two NMOS transistors, that is, first and second NMOS transistors 309 and 311, and an inverter 313. In a MOS transistor, a reverse bias should be applied to PN junction between a source and a substrate (or body) and PN junction between a drain and a substrate. In the embodiment, the same input power supply VDDH is applied to sources of the first and second PMOS transistors 305 and 307, and the maximum value of the first output voltage OUT1 is also V_{DDH}, and thus, a body is connected to a source so that a reverse bias is applied to PN junction between a source and a body and to PN junction between a drain and a body. However, different input voltages are applied to sources of a third PMOS transistor 301 and a fourth PMOS transistor 303, and the second output voltage OUT2 is transited between the first power supply V_{DDH} and the second power supply V_{DDL}, and thus, a body is floated so that a reverse bias is applied to PN junction between a source and a body and to PN junction between a drain and a body. The first and second NMOS transistors 309 and 311 can be implemented with one of a thin gate MOS transistor or a thick gate MOS transistor. When the first and second NMOS transistor 309 and 311 are implemented with a thick gate MOS transistor, the breakdown voltage of a gate increases, resulting in applying a high voltage. The first control signal shown in FIG. 2 is a signal, which is commonly connected to a gate of the first PMOS transistor 305, a drain of the first NMOS transistor 309, and a gate of the second PMOS transistor 307, and controls the operation of the third PMOS transistor 301 depending on each transistor, which is turned on/off according to the input signal IN. The second control signal shown in FIG. 2 can be constituted of an extra circuit but in the embodiment, is a signal, which is the same as the first output voltage OUT1, controls the operation of the fourth PMOS transistor 303.

Hereinafter, the detailed operation will be described with reference to FIG. 3. First, the detailed operation of the first level shifter 203 will be described. The input signal IN having a logic signal level (here, the same level as that of the second power supply V_{DDL}) is connected to a gate of the first NMOS transistor 309, and the input signal IN, which is inverted by the inverter 313, is connected to a gate of the second NMOS transistor 311. The drains of the first and second NMOS transistors 309 and 311 are grounded together. When the input signal IN is logic signal “low”, the first NMOS transistor 309 is turned off, and the second NMOS transistor 311 is turned on. As a result, the first PMOS transistor 305 is turned on, the second PMOS transistor 307 is turned off, and thus, the first output voltage OUT1 becomes 0V. Simultaneously, the third PMOS transistor 301 is turned off, the fourth PMOS transistor 303 is turned on, and thus, the first input power supply VDDH is output as the second output voltage OUT2.

Next, a case where the input signal IN is logic signal “high” will be described. When the input signal IN is logic signal “high” (here, the same level as that of the second power supply VDDL), the first NMOS transistor 309 is turned on, and the second NMOS transistor 311 is turned off. As a result, the first PMOS transistor 305 is turned off, the second PMOS transistor 307 is turned on, and thus, the first output voltage OUT1 becomes the first power supply VDDH. Simultaneously, the third PMOS transistor 301 is turned on, the fourth PMOS transistor 303 is turned off, and thus, the second power supply VDDL is output as the second output voltage OUT2. Likewise, the level shifter simultaneously generates the first output voltage OUT1 and the second output voltage OUT2 having different levels.

FIG. 4 illustrates a waveform of an input signal and an output signal of the level shifter according to the present invention, and FIG. 5 illustrates results of simulation of the operation of the level shifter according to the present invention. When input 501 is logic “low”, the first output voltage OUT1 (503) is 0V, and the first input power supply V_{DDH} (507) is output as the second output voltage OUT2 (505). When the input 501 is logic “high”, the first input power supply V_{DDH} (507) is output as the first output voltage OUT1 (503), and the second input power supply V_{DDL} (507) is output as the second output voltage OUT2 (505). In the embodiment, the first input power supply V_{DDH} (507) is 10V, and the second input power supply V_{DDL} (507) is 5V. The embodiment is limited to the first through fourth PMOS transistors and the first and second NMOS transistors but each of the transistors can be implemented with a 3-terminal element having a different configuration by reconnecting each of terminals.

As described above, the level shifter for generating a plurality of output voltages having a plurality of levels according to the present invention can output voltages having levels different according to a power supply applied to one level shifter, and thus, interface a low voltage circuit with a high voltage circuit can be very easily made and various applications thereof are possible.

While this invention has been particularly shown and described with reference to preferred embodiments thereof, it will be understood by those skilled in the art that various changes in form and details may be made therein without departing from the spirit and scope of the invention as defined by the appended claims.

What is claimed is:

1. A level shifter comprising:
a first level shifter for receiving an input signal and a first power supply and outputting a first output voltage having a level the same as that of a ground voltage or the first power supply according to the input signal, a first control signal having a value in which the first output voltage is inverted, and a second control signal having the same value as that of the first output voltage; and
an output voltage generator for receiving the first power supply and a second power supply having a level different from that of the first power supply and outputting a second output voltage having a level equivalent to either the first power supply or the second power supply according to the first and second control signals.

2. The level shifter of claim 1, wherein the first level shifter comprises:
first and second PMOS transistors of which drains and gates are cross-coupled;
a first NMOS transistor, a gate of the first NMOS transistor is connected to the input signal, a source of the first NMOS transistor is grounded, and a drain of the first NMOS transistor is connected to a drain of the first PMOS transistor;
an inverter for inverting the input signal and outputting the inverted signal; and
a second NMOS transistor, a gate of the second NMOS transistor is connected to the output signal of the inverter, a source of the second NMOS transistor is grounded, and a drain of the second NMOS transistor is connected to a drain of the second PMOS transistor.

3. The level shifter of claim 1, wherein the output voltage generator includes third and fourth PMOS transistors, sources of the third and fourth PMOS transistors are connected to the first and second power supplies, respectively, gates of the third and fourth PMOS transistors are connected to the first and second control signals, respectively, and drains of the third and fourth PMOS transistors are commonly connected to each other, which output the second output voltage in response to the first and second control signals.

4. The level shifter of claim 2, wherein the first and second PMOS transistors are high voltage PMOS transistors of which bodies are connected to sources of the high voltage PMOS transistors.

5. The level shifter of claim 3, wherein the third and fourth PMOS transistors are high voltage PMOS transistors of which bodies are floated.

6. A level shifter comprising:
first and second transistors, first and second terminals of the first and second transistors are cross-coupled, and a first power supply is applied to third terminals of the first and second transistors;
a controller for outputting first and second control signals having a predetermined voltage level in response to an input signal;
a third transistor, a second power supply is applied to a third terminal of the third transistor, the first terminal of the first transistor and the first control signal are connected to a second terminal of the third transistor, which generates a second output voltage having a plurality of voltage levels to the first terminal of the third transistor in response to the first control signal; and
a fourth transistor, the first power supply is applied to a third terminal of the fourth transistor, a first terminal of the fourth transistor is connected to the first terminal of the third transistor, a second terminal of the fourth transistor is connected to the first terminal of the second transistor and the second control signal, which generates the second output voltage to the first terminal of the fourth transistor in response to the second control signal.

7. The level shifter of claim 6, wherein the controller comprises:
an inverter for inverting the input signal and outputting the inverted signal;
a fifth transistor, a second terminal of the fifth transistor is connected to the input signal, a third terminal of the fifth transistor is grounded, which outputs the first control signal to a first terminal of the fifth transistor according to the input signal; and
a sixth transistor, a second terminal of the sixth transistor is connected to output of the inverter, a third terminal of the sixth transistor is grounded, which outputs the second control signal to a first terminal of the sixth transistor according to the output of the inverter.

8. The level shifter of claim 7, wherein the fifth and sixth transistors are NMOS transistors, the first terminals of the fifth and sixth transistors are drains, the second terminals of the fifth and sixth transistors are gates, and the third terminals of the fifth and sixth transistors are sources.

9. The level shifter of claim 6, wherein the first and second transistors are PMOS transistors, the first terminals of the first and second transistors are drains, the second terminals of the first and second transistors are gates, and the third terminals of the first and second transistors are sources.

10. The level shifter of claim 9, wherein the first and second transistors are high voltage PMOS transistors of which bodies are connected to sources of the high voltage PMOS transistors.

11. The level shifter of claim 6, wherein the third and fourth transistors are PMOS transistors, first terminals of the third and fourth transistors are drains, second terminals of the third and fourth transistors are gates, and third terminals of the third and fourth transistors are sources.

12. The level shifter of claim 11, wherein the third and fourth transistors are high voltage PMOS transistors of which bodies are floated.
